(19) United States
(12) Patent Application Publication
(10) Pub. No.: US 2026/0231331 A1
(43) Pub. Date: Aug. 6, 2026

(54) WIRING SUBSTRATE AND METHOD FOR MANUFACTURING THE SAME

(71) Applicant: IBIDEN CO., LTD., Gifu (JP)

(72) Inventor: Takema ADACHI, Gifu (JP)

(73) Assignee: IBIDEN CO., LTD., Gifu (JP)

(21) Appl. No.: 19/463,359

(22) Filed: Jan. 29, 2026

(30) Foreign Application Priority Data
Jan. 29, 2025 (JP) 2025-013396

(51) Int. Cl. H05K 1/16; H05K 1/03; H05K 1/11; H05K 3/42; H05K 3/00

(52) U.S. Cl. CPC H05K 1/165; H05K 1/0373; H05K 1/115; H05K 3/42; H05K 3/0032; H05K 3/0047; H05K 2201/0215; H05K 2201/0959

(57) ABSTRACT

A wiring substrate includes a core substrate including a main body and a magnetic resin body, and through-hole conductors formed in the magnetic resin body in the core substrate such that the through-hole conductors are penetrating through the magnetic resin body in the core substrate. The core substrate is formed such that an inter-conductor material is positioned between the through-hole conductors in the magnetic resin body and that the inter-conductor material has magnetism that is lower than magnetism of the magnetic resin body or is non-magnetic.

### CROSS-REFERENCE TO RELATED APPLICATIONS

The present application is based upon and claims the benefit of priority to Japanese Patent Application No. 2025-013396, filed January 29, 2025, the entire contents of which are incorporated herein by reference.

### BACKGROUND OF THE INVENTION

### Field of the Invention

The present invention relates to a wiring substrate having multiple through-hole conductors and a method for manufacturing the same.

### Description of Background Art

Japanese Patent Application Laid-Open Publication No. 2021-97128 describes a wiring substrate in which a magnetic resin body is provided in a core substrate and multiple through-hole conductors are provided in the magnetic resin body. The entire contents of this publication are incorporated herein by reference.

### SUMMARY OF THE INVENTION

According to one aspect of the present invention, a wiring substrate includes a core substrate including a main body and a magnetic resin body, and through-hole conductors formed in the magnetic resin body in the core substrate such that the through-hole conductors are penetrating through the magnetic resin body in the core substrate. The core substrate is formed such that an inter-conductor material is positioned between the through-hole conductors in the magnetic resin body and that the inter-conductor material has magnetism that is lower than magnetism of the magnetic resin body or is non-magnetic.

According to another aspect of the present invention, a method for manufacturing a wiring substrate includes forming an accommodating portion in a main body of a core substrate, filling the accommodating portion formed in the main body of the core substrate with a magnetic resin body paste such that a magnetic resin body is formed in the core substrate, forming through-hole conductors in the magnetic resin body of the core substrate such that the through-hole conductors penetrate through the magnetic resin body in the core substrate, and forming an inter-conductor material in the core substrate such that the inter-conductor material is positioned between the through-hole conductors in the magnetic resin body of the core substrate and that the inter-conductor material has magnetism that is lower than the magnetic resin body or is non-magnetic.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring substrate according to a first embodiment of the present invention;

FIG. 2A is a cross-sectional view of a magnetic resin body;

FIG. 2B is a cross-sectional view taken along a line (A-A) in FIG. 2A;

FIG. 3A is an image diagram of a magnetic path in a case where no inter-conductor material is provided;

FIG. 3B is an image diagram of a magnetic path in a case where an inter-conductor material is provided;

FIGS. 4A and 4B are cross-sectional views illustrating manufacturing processes of a wiring substrate according to an embodiment of the present invention;

FIGS. 5A and 5B are cross-sectional views illustrating manufacturing processes of a wiring substrate according to an embodiment of the present invention;

FIGS. 6A and 6B are cross-sectional views illustrating manufacturing processes of a wiring substrate according to an embodiment of the present invention;

FIGS. 7A, 7B and 7C are cross-sectional views illustrating manufacturing processes of a wiring substrate according to an embodiment of the present invention;

FIGS. 8A and 8B are cross-sectional views illustrating manufacturing processes of a wiring substrate according to an embodiment of the present invention;

FIGS. 9A and 9B are cross-sectional views illustrating manufacturing processes of a wiring substrate according to an embodiment of the present invention;

FIG. 10 is a cross-sectional view of a magnetic resin body according to a second embodiment;

FIGS. 11A to 11D are cross-sectional views illustrating manufacturing processes of a wiring substrate according to an embodiment of the present invention;

FIG. 12A is a cross-sectional view of a magnetic resin body according to a third embodiment;

FIG. 12B is an enlarged cross-sectional view of the magnetic resin body;

FIG. 12C is a cross-sectional view taken along a line (B-B) in FIG. 12A;

FIG. 13A is a cross-sectional view of a magnetic resin body according to a fourth embodiment;

FIG. 13B is an image diagram of a magnetic path;

FIGS. 14A to 14C are cross-sectional views illustrating manufacturing processes of a wiring substrate according to an embodiment of the present invention; and

FIGS. 15A and 15B are cross-sectional views of a magnetic resin body of a wiring substrate of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

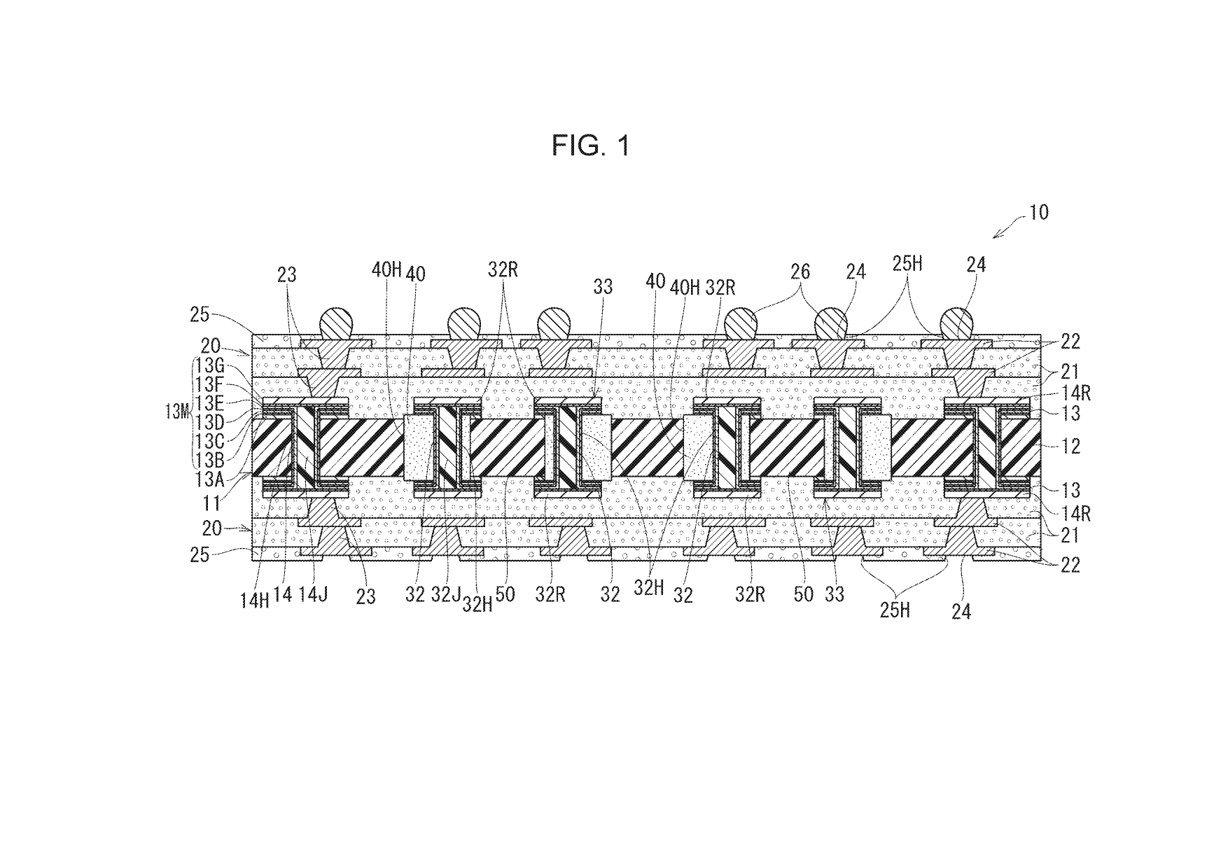

The present embodiment is described with reference to FIGS. 1 to 9. As illustrated in FIG. 1, a wiring substrate 10 according to an embodiment of the present invention includes, for example, a core substrate 11, and build-up layers 20 that are respectively laminated on front and back surfaces of the core substrate 11.

Each build-up layer 20 includes insulating layers 21 and conductive layers 22 that are alternately laminated, and via conductors 23 that connect adjacent conductive layers 22 to each other. A solder resist layer 25 is laminated on an outermost conductive layer 22 of each build-up layer 20. The solder resist layer 25 has multiple openings (25H) corresponding to multiple pads 24 included in the outermost conductive layer 22. Multiple solder bumps 26 are provided on all or some of the multiple pads 24.

The core substrate 11 includes an insulating layer 12. Multiple accommodating portions (40H) are formed in the insulating layer 12, and these multiple accommodating portions (40H) are each filled with a magnetic resin body 40. The magnetic resin body 40 is a resin containing magnetic particles, and for the magnetic particles, for example, iron oxide, nickel, nickel alloy, cobalt, or tin is used, while for the resin, for example, epoxy resin, phenol resin, or the like is used. The insulating layer 12 is composed of, for example, a prepreg formed by impregnating a woven fabric of reinforcing fibers (for example, glass cloth) with resin, and has lower magnetism than the magnetic resin body 40 or is non-magnetic having no magnetism.

The core substrate 11 includes conductive layers 13, which are respectively laminated on front and back surfaces of the insulating layer 12 that contains the magnetic resin body 40. Further, as through-hole conductors that connect between these conductive layers 13, multiple through-hole conductors 14 are provided in the insulating layer 12, which is a non-magnetic portion, and multiple through-hole conductors 32 are provided in the magnetic resin body 40. Through-hole lands (14R, 32R) included in the conductive layers 13 are provided at ends of the through-hole conductors (14, 32). The multiple through-hole conductors (14, 32) are formed on inner side surfaces of multiple through holes (14H, 32H) that penetrate the insulating layer 12 or the magnetic resin body 40, and are filled inside with resins (14J, 32J). Further, the conductive layers (13, 22) are also connected to each other by via conductors 23.

In each conductive layer 13, a plating film (13M) is laminated on a metal foil (13A) (for example, a copper foil). The plating film (13M) is formed of, in order from the metal foil (13A) side, a first electroless plating film (13B), a first electrolytic plating film (13C), a second electroless plating film (13D), a second electrolytic plating film (13E), a third electroless plating film (13F), and a third electrolytic plating film (13G). Of the plating film (13M), the first electroless plating film (13B) and the first electrolytic plating film (13C) serve as a shield plating that covers end faces of the magnetic resin body 40, as will be described in a manufacturing method below; the second electroless plating film (13D) and the second electrolytic plating film (13E) serve as through-hole plating that forms the multiple through-hole conductors (14, 32); and the third electroless plating film (13F) and the third electrolytic plating film (13G) serve as cover plating that covers the resins (14J, 32J).

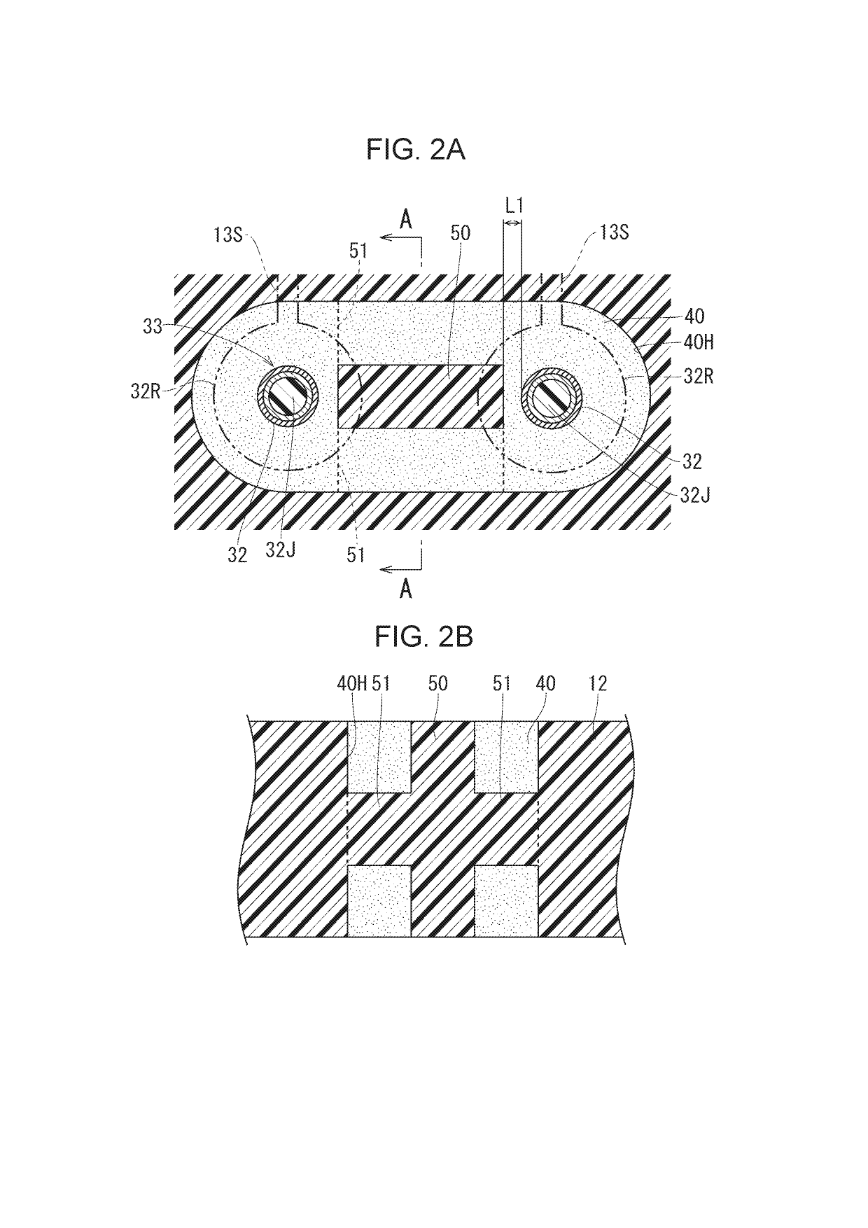

As described above, multiple through-hole conductors 32 are provided in each magnetic resin body 40. As illustrated in FIG. 2A, the magnetic resin body 40 has, for example, an oval cross-section, and the multiple through-hole conductors 32 are formed side by side such that, for example, their central axes are aligned on a centerline in a width direction of the magnetic resin body 40. Further, the through-hole lands (32R) of these multiple through-hole conductors 32 are circular in plan view and have a size that fits within an outer edge of the magnetic resin body 40. Further, the through-hole lands (32R) are respectively connected to wirings (13S) that respectively extend toward through-hole lands (32R) of multiple through-hole conductors 32 provided in another magnetic resin body 40 (not illustrated in FIG. 2A), and an inductor 33 is formed by these multiple through-hole conductors 32, multiple through-hole lands (32R), and wirings (13S). In the wiring substrate 10, in a circuit that includes the inductor 33, directions of currents flowing through the multiple through-hole conductors 32 of the common magnetic resin body 40 are the same.

As illustrated in FIGS. 2A and 2B, in the magnetic resin body 40 of the present embodiment, an inter-conductor material 50 and a pair of connecting portions 51 are provided. The inter-conductor material 50 and the pair of connecting portions 51 are provided in the magnetic resin body 40, between adjacent through-hole conductors 32, so as to bridge between opposing inner surfaces in a short-side direction of the accommodating portion (40H).

The inter-conductor material 50 has, for example, a quadrangular shape in plan view and penetrates the magnetic resin body 40. The inter-conductor material 50 is formed in the magnetic resin body 40 on an imaginary line connecting the central axes of adjacent through-hole conductors 32, and its width is, for example, substantially the same as or larger than an outer diameter of the through-hole conductors 32. Further, it is preferable to position the inter-conductor material 50 such that both ends thereof are as close as possible to the through-hole conductors 32, and for example, a shortest distance (L1) between the inter-conductor material 50 and the outer diameter of the through-hole conductors 32 is 5 to 15 μm.

The pair of connecting portions 51 respectively protrude from the opposing inner surfaces in the short-side direction of the accommodating portion (40H) and are each connected to the inter-conductor material 50. The pair of connecting portions 51 have the same size as the inter-conductor material 50 in a longitudinal direction of the accommodating portion (40H). Further, the pair of connecting portions 51 are formed at an intermediate position in a thickness direction of the magnetic resin body 40, and their thickness is, for example, about 1/2 to 1/5 (preferably, for example, about 1/3) of the magnetic resin body 40.

In the example illustrated in FIG. 2B, the pair of connecting portions 51 are formed at a central portion in the thickness direction of the magnetic resin body 40. However, the pair of connecting portions 51 may be formed offset toward either side in the thickness direction. Further, the pair of connecting portions 51 are formed at the same position in the thickness direction. However, the pair of connecting portions 51 may be formed at different positions.

Further, in the present embodiment, the inter-conductor material 50 and the pair of connecting portions 51 are constituted by the insulating layer 12 and, as described above, have lower magnetism than the magnetic resin body 40 or are non-magnetic.

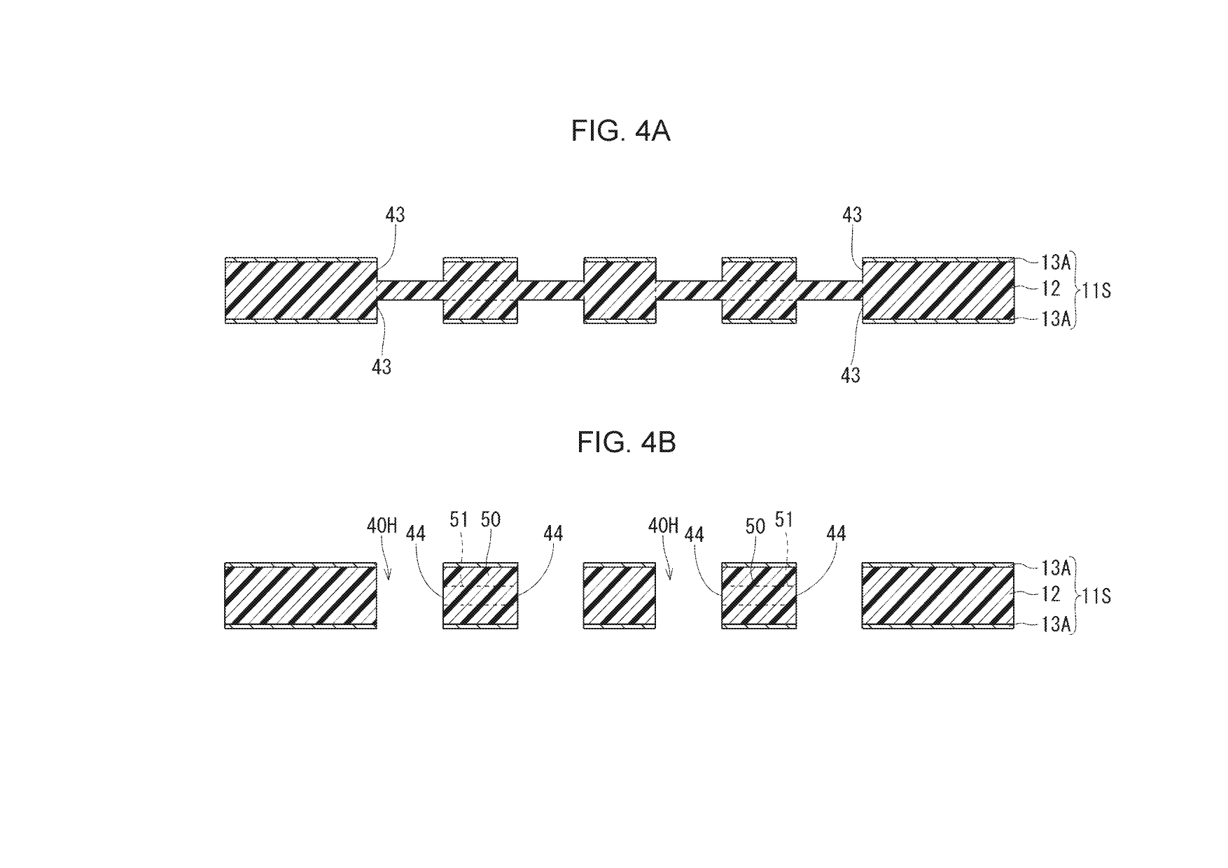

The wiring substrate 10 is manufactured as follows. (1) A laminated board (11S) is prepared in which the metal foil (13A) is laminated on both the front and back surfaces of the insulating layer 12. Then, as illustrated in FIG. 4A, grooves 43 are formed, for example by laser processing, on both front and back surfaces of the laminated board (11S) at positions where the multiple accommodating portions (40H) are to be formed. The grooves 43 have an annular shape so as to surround a portion that will become the inter-conductor material 50. Further, a depth of each groove 43 is, for example, about 1/5 to 1/3 of a thickness of the laminated board (11S). Portions of bottom surfaces of the grooves 43 become end faces of the pair of connecting portions 51.

(2) Next, through holes 44 are formed by drilling in both end portions of each groove 43 (in other words, portions other than portions that will become the inter-conductor material 50 and the pair of connecting portions 51). As a result, as illustrated in FIG. 4B, the accommodating portions (40H) each having an inter-conductor material 50 and a pair of connecting portions 51 inside are formed.

The process of forming the accommodating portion (40H) may be performed by carrying out the above process (2) first, and then the above process (1). Specifically, first, a pair of through holes are formed in the laminated board (11S) by drilling. Next, on the front surface side of the laminated board (11S), a pair of grooves are formed so as to connect the pair of through holes 44 on both sides sandwiching a portion that will become the inter-conductor material 50. Then, similarly on the back surface side of the laminated board (11S), a pair of grooves are formed so as to connect between the pair of through holes 44.

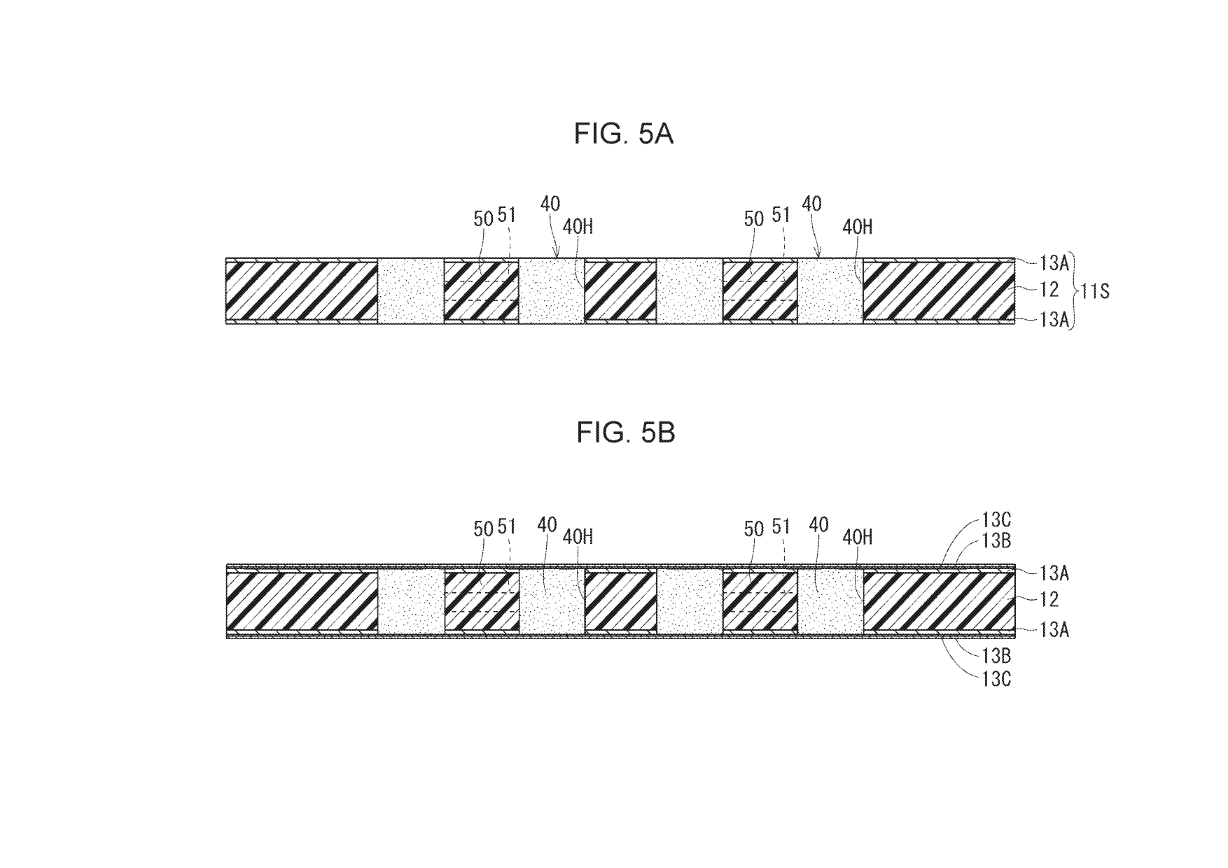

(3) As illustrated in FIG. 5A, the multiple accommodating portions (40H) are filled with a paste of the magnetic resin body 40 by vacuum printing. Specifically, first, a tape (not illustrated) is attached to lower ends of the multiple accommodating portions (40H) in the laminated board (11S), and the paste of the magnetic resin body 40 is filled from upper ends of the multiple accommodating portions (40H). Next, the upper ends of the multiple accommodating portions (40H) are closed with a tape (not illustrated). Then, the laminated board (11S) is turned over, the tape that is now on the upper end side is peeled off, and the paste of the magnetic resin body 40 is filled from the upper ends. This facilitates spreading of the paste of the magnetic resin body 40 throughout each entire accommodating portion (40H). Next, after all tapes have been peeled off, both end surfaces of the magnetic resin body 40 are polished so as to be flush with the laminated board (11S). As a result, both end faces of the magnetic resin body 40 become substantially flush with the metal foil (13A).

(4) Next, an electroless plating process and an electrolytic plating process are performed, and the first electroless plating film (13B) and the first electrolytic plating film (13C) are laminated on both the front and back surfaces of the laminated board (11S) including the magnetic resin body 40 (see FIG. 5B).

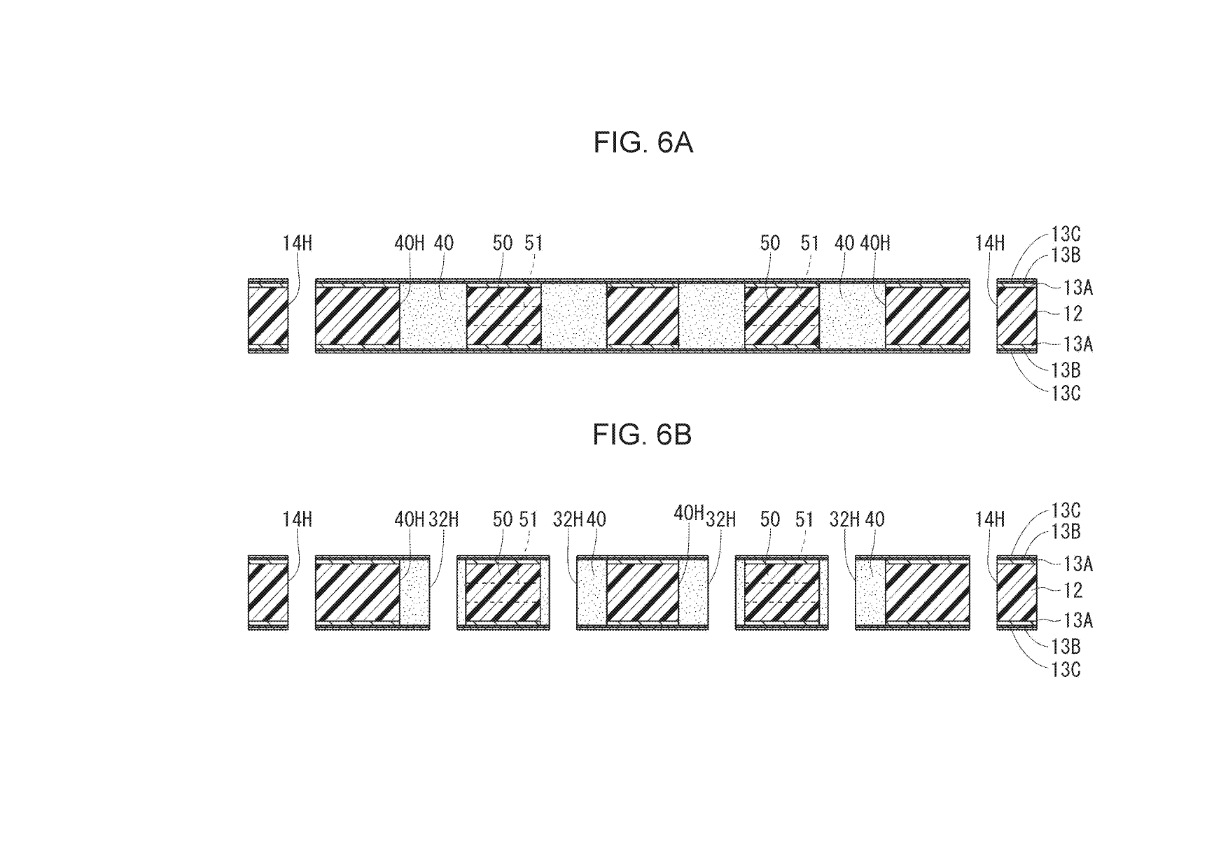

(5) As illustrated in FIG. 6A, the through holes (14H) are formed at positions where the multiple through-hole conductors 14 are to be formed, and a desmear treatment is performed. In this desmear treatment, smear is removed using a desmear solution (for example, potassium permanganate). The end surfaces of the magnetic resin body 40 are covered by the first electroless plating film (13B) and the first electrolytic plating film (13C), which are formed in the above process (4), and thus, are prevented from coming into contact with the desmear solution.

(6) Next, as illustrated in FIG. 6B, the through holes (32H) are formed at positions where the multiple through-hole conductors 32 are to be formed, and a desmear treatment is performed. In this desmear treatment, smear is removed by medium-pressure water washing or high-pressure water washing, rather than using the desmear solution of the above process (5).

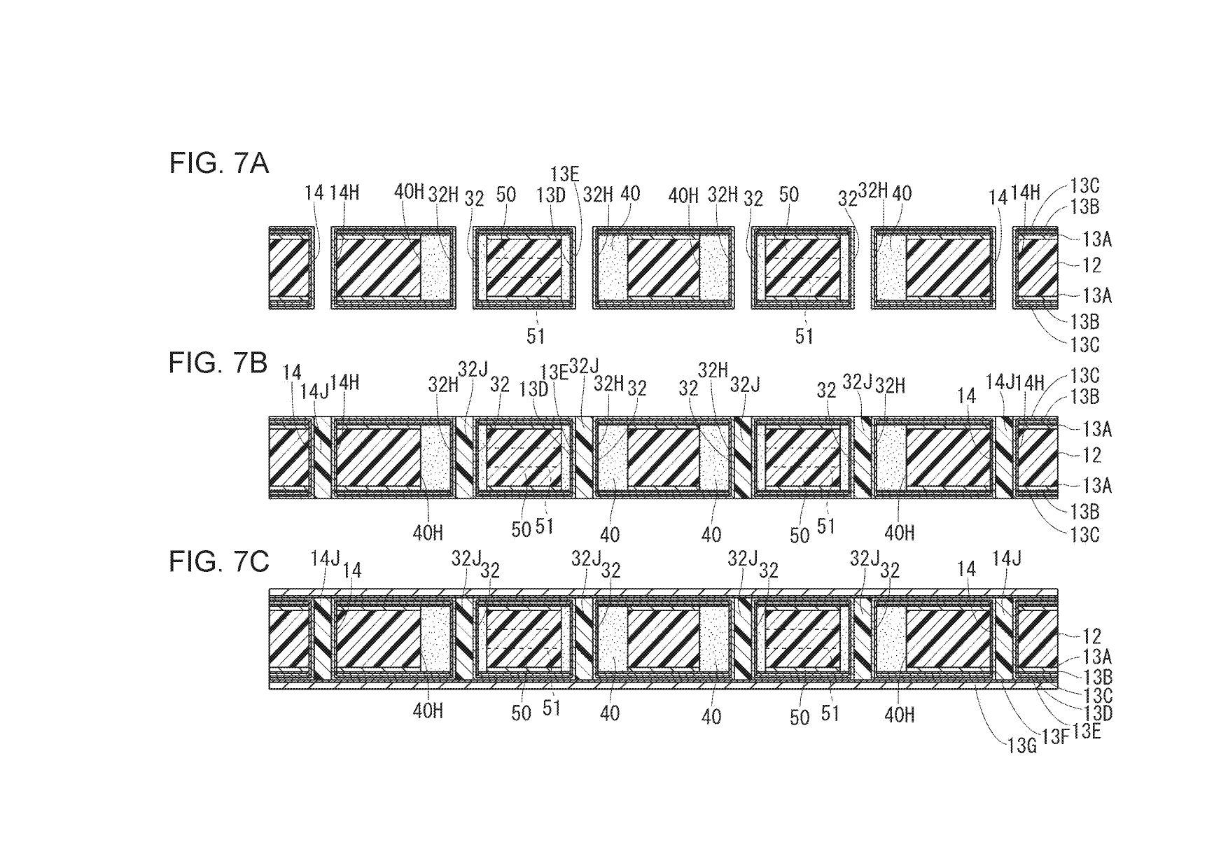

(7) As illustrated in FIG. 7A, an electroless plating process and an electrolytic plating process are performed, and the second electroless plating film (13D) and the second electrolytic plating film (13E) are laminated on inner surfaces of the multiple through holes (14H, 32H) and on the first electrolytic plating film (13C). As a result, the multiple through-hole conductors (14, 32) are obtained.

(8) As illustrated in FIG. 7B, the resins (14J, 32J) are filled into the multiple through-hole conductors (14, 32), and end surfaces of the resins (14J, 32J) are polished so as to be substantially flush with the second electrolytic plating film (13E).

(9) Next, an electroless plating process and an electrolytic plating process are performed. As a result, as illustrated in FIG. 7C, the third electroless plating film (13F) and the third electrolytic plating film (13G) are formed on the second electrolytic plating film (13E) and on the exposed surfaces (end surfaces) of the resins (14J, 32J).

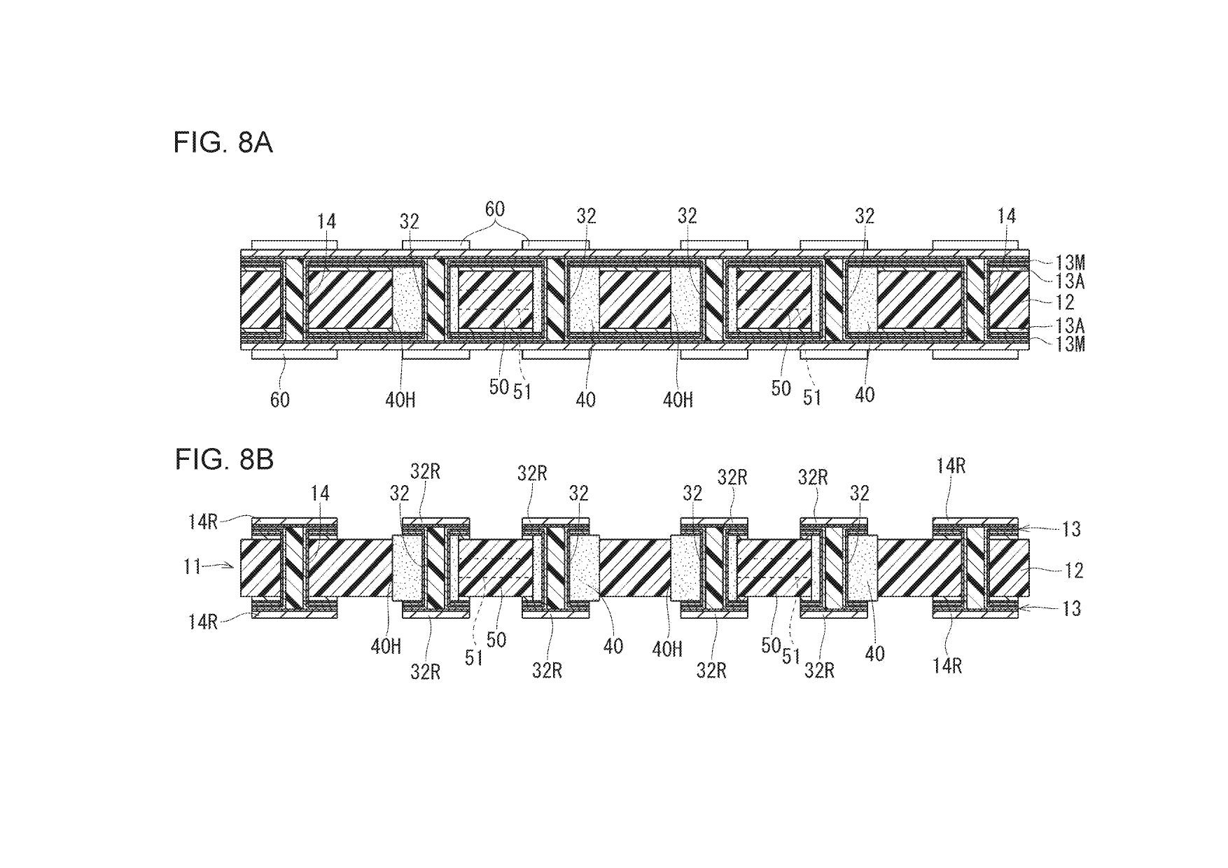

(10) As illustrated in FIG. 8A, an etching resist 60 having predetermined patterns is formed on the plating film (13M).

(11) Etching processing is performed, whereby the metal foil (13A) and the plating film (13M) exposed from the etching resist 60 are removed. After that, the etching resist 60 is removed. As a result, as illustrated in FIG. 8B, the conductive layers 13 including the multiple through-hole lands (14R, 32R) are formed on both the front and back surfaces of the insulating layer 12, and the core substrate 11 is obtained.

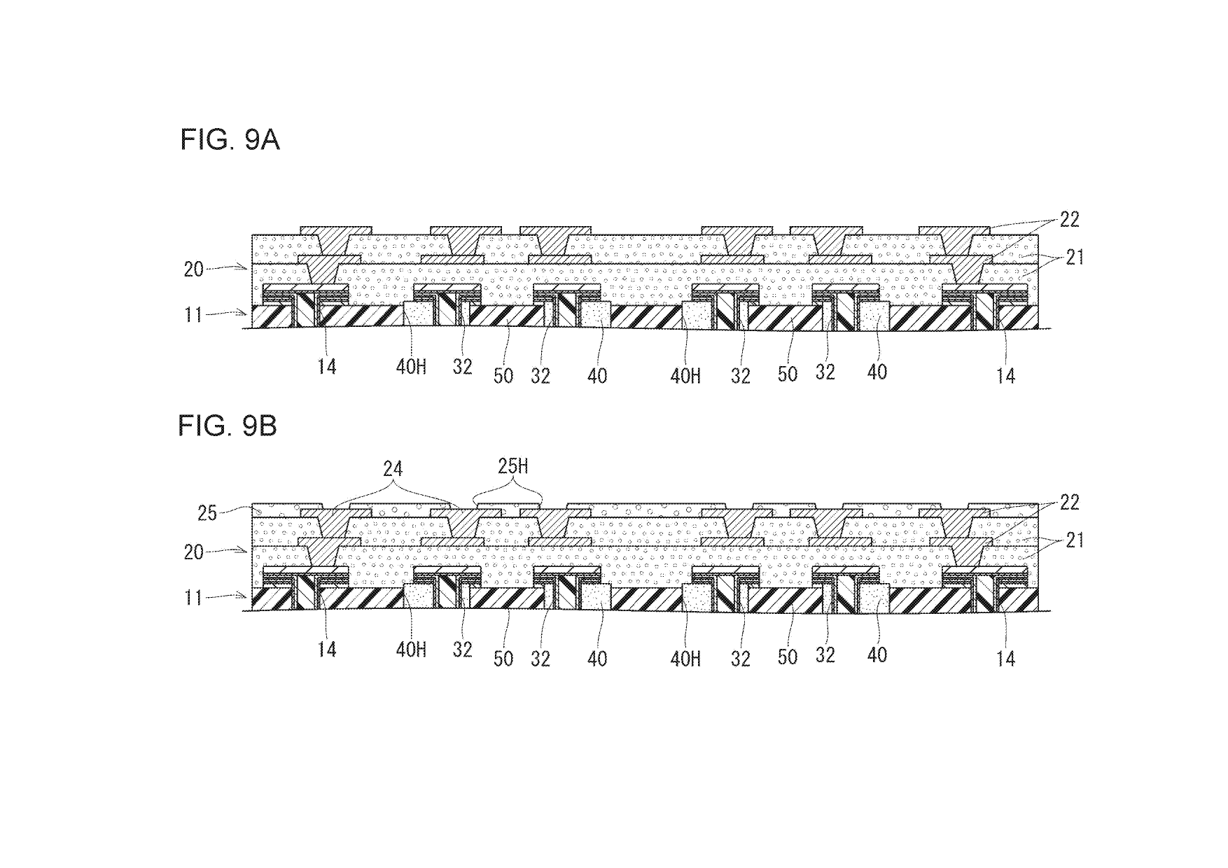

(12) Next, using an SAP method (Semi-Additive Process), the insulating layers 21 and the conductive layers 22 are alternately laminated, and build-up layers 20 are formed on both the front and back surfaces of the core substrate 11 (see FIG. 9A). In FIGS. 9A and 9B, only one of the build-up layers 20 is illustrated.

(13) As illustrated in FIG. 9B, the solder resist layer 25 having the multiple openings (25H) is laminated on the outermost conductive layer 22. As a result, the multiple pads 24 exposed from the multiple openings (25H) of the solder resist layer 25 are formed.

(14) Next, for example, solder balls are affixed to some or all of the multiple pads 24 to form the multiple solder bumps 26 (see FIG. 1). As a result, the wiring substrate 10 is formed.

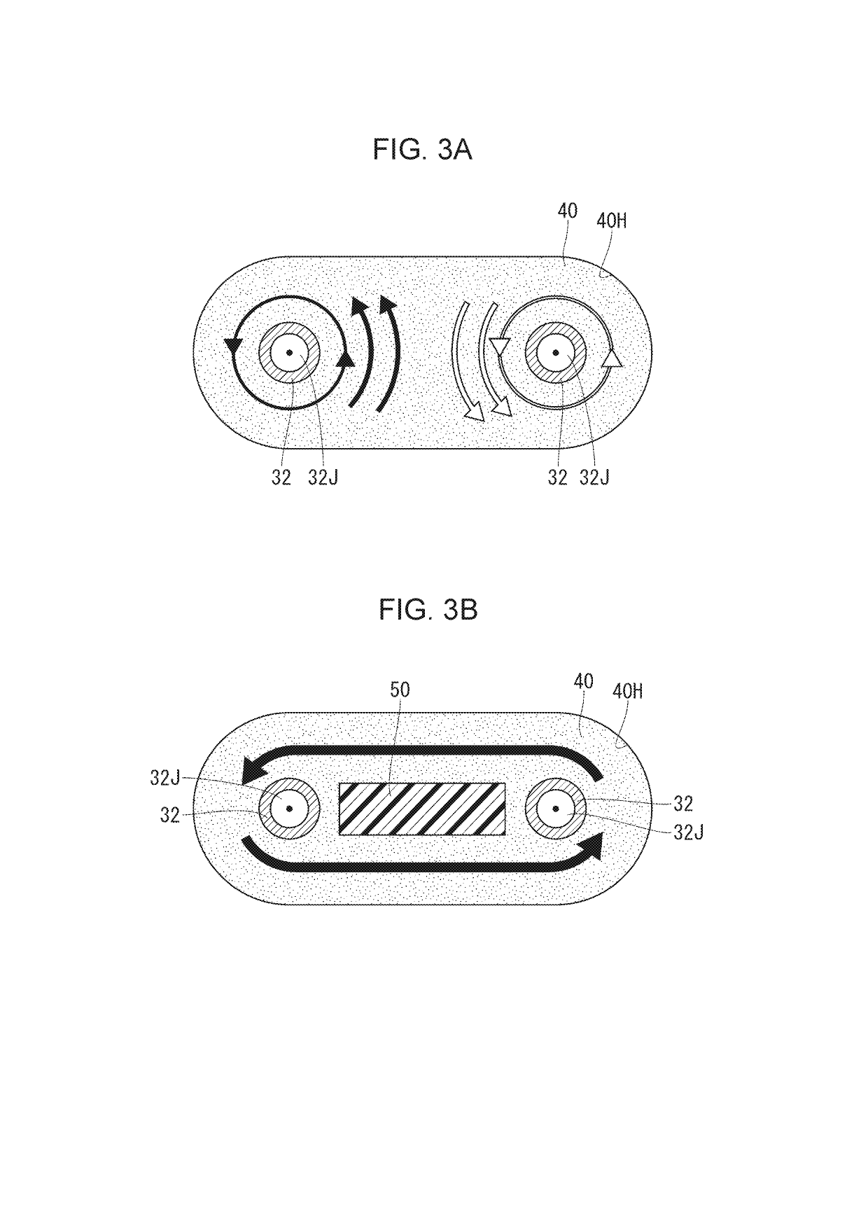

Next, operational effects of the wiring substrate 10 of the present embodiment are described. First, problems in a case where the inter-conductor material 50 is not provided between the multiple through-hole conductors 32 in a common magnetic resin body 40 are described. As illustrated in FIG. 3A, in the case where the inter-conductor material 50 is not provided between the multiple through-hole conductors 32 in the magnetic resin body 40, when current flows through the multiple through-hole conductors 32 from the back side toward the front side of the paper of FIG. 3A, a counterclockwise magnetic field centered on each through-hole conductor 32 is generated. In this case, between adjacent through-hole conductors 32, directions of two magnetic fields are opposite, and thus there is a problem that the magnetic fields cancel each other out.

In contrast, in the present embodiment, in the magnetic resin body 40, the inter-conductor material 50 that has lower magnetism than the magnetic resin body 40 or is non-magnetic is formed between adjacent through-hole conductors 32. As a result, as illustrated in FIG. 3B, magnetic flux lines of the magnetic field generated by current flowing through each through-hole conductor 32 pass along an outer edge portion of the magnetic resin body 40, which has higher magnetism than the inter-conductor material 50, and consequently, a magnetic field is generated so as to collectively surround the multiple through-hole conductors 32. That is, by positioning the inter-conductor material 50 between the multiple through-hole conductors 32, a bypass path of a magnetic path that collectively surrounds the multiple through-hole conductors 32 is formed. In this manner, in the present embodiment, cancellation of magnetic fields acting between adjacent through-hole conductors 32 is reduced, and a magnetic field is strengthened, and thus inductance is improved.

Further, in the present embodiment, since the inter-conductor material 50 is composed of the same material as the insulating layer 12, a difference in magnetism is unlikely to occur in a width direction of the bypass path of the magnetic path. Moreover, in the present embodiment, since the inter-conductor material 50 is fixed via the pair of connecting portions 51, displacement of the inter-conductor material 50 during formation of the magnetic resin body 40 can be suppressed.

### Second Embodiment

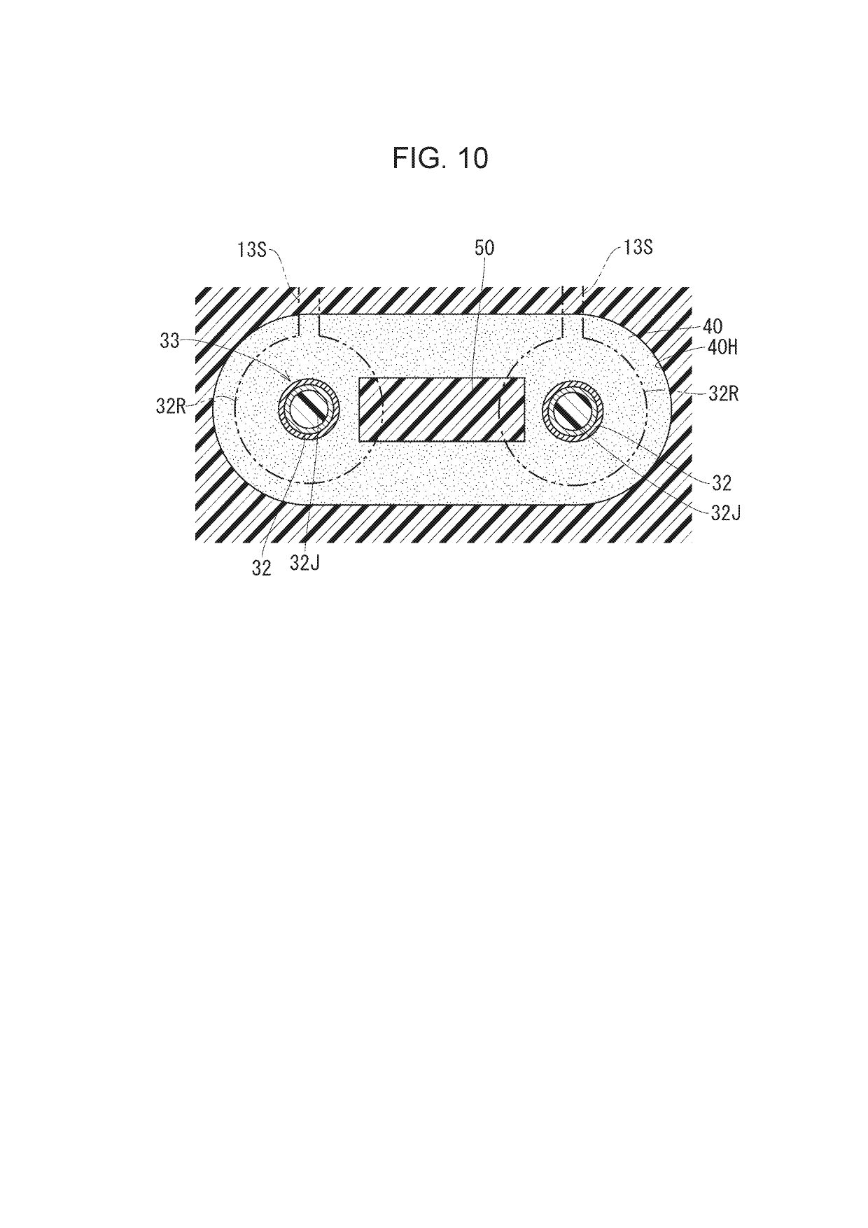

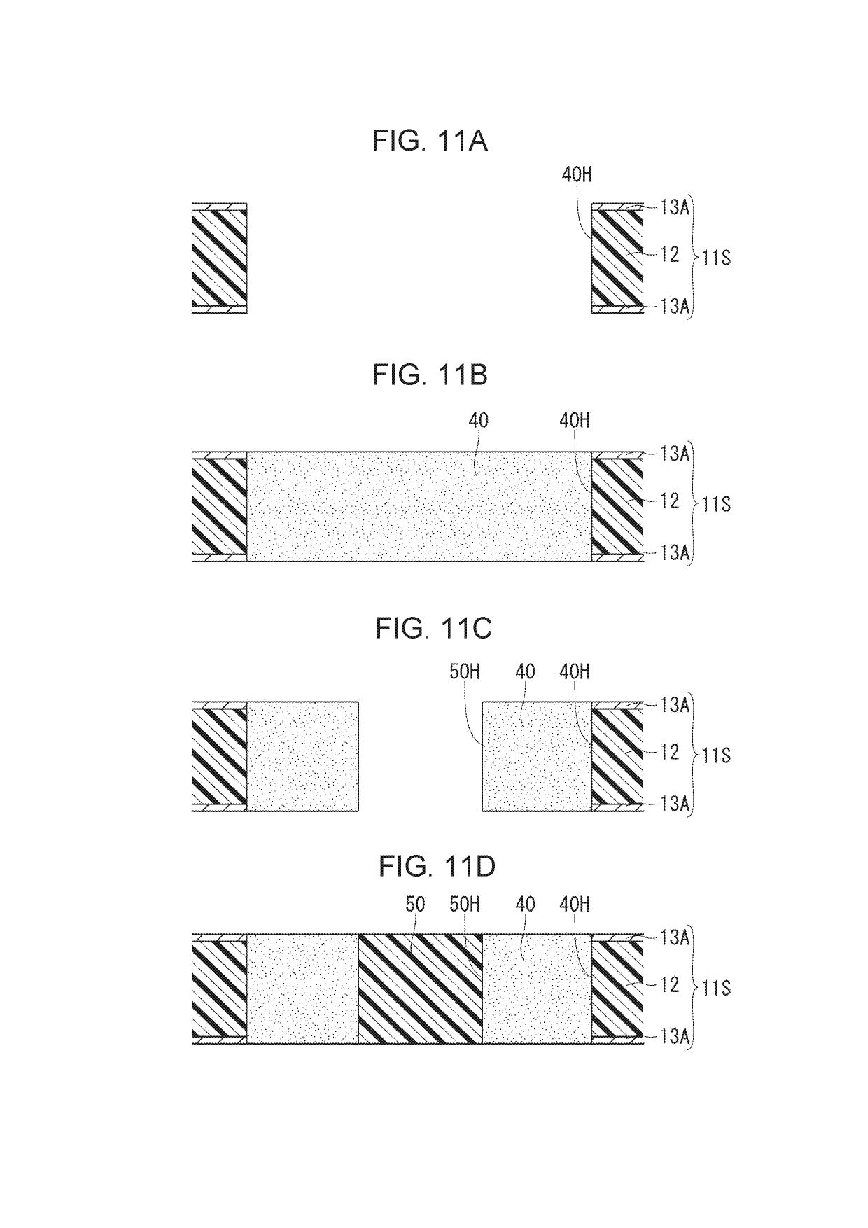

A magnetic resin body 40 according to an embodiment of the present invention is illustrated in FIG. 10 and differs from the first embodiment only in that it does not have the pair of connecting portions 51. Further, in a method for manufacturing a wiring substrate 10 of the present embodiment, the following processes (1) to (4) are performed in place of the processes (1) to (3) of the first embodiment. In FIGS. 11A to 11D, only one magnetic resin body 40 of the wiring substrate 10 is illustrated.

(1) As illustrated in FIG. 11A, multiple accommodating portions (40H) are formed in the laminated board (11S), for example, by drilling.

(2) As illustrated in FIG. 11B, after the multiple accommodating portions (40H) are filled with a paste of the magnetic resin body 40, both end surfaces of the magnetic resin body 40 are polished so as to be flush with the metal foil (13A).

(3) As illustrated in FIG. 11C, in each magnetic resin body 40, a through hole (50H) is formed, for example by drilling, at a position where the inter-conductor material 50 is to be formed.

(4) As illustrated in FIG. 11D, after the through hole (50H) of each magnetic resin body 40 is filled, for example, with a resin paste of the same material as the insulating layer 12, both end surfaces of the inter-conductor material 50 are polished so as to be flush with the metal foil (13A).

In the present embodiment, the same effects as in the first embodiment are achieved, and since the pair of connecting portions 51 are not provided, a uniform magnetic field is obtained in the thickness direction between the multiple through-hole conductors 32.

The inter-conductor material 50 illustrated in FIG. 10 penetrates the magnetic resin body 40. However, for example, it is also possible that the inter-conductor material 50 does not penetrate the magnetic resin body 40. Specifically, in the above process (3), a recess (not illustrated) may be formed instead of the through hole (50H), and in the above process (4), the recess may be filled with resin, thereby forming an inter-conductor material that does not penetrate the magnetic resin body 40.

The inter-conductor material 50 is not limited to the same material as the insulating layer 12, and may be any material that has lower magnetism than the magnetic resin body 40 or has no magnetism, such as, for example, the resin (32J) filled inside the through-hole conductors 32, air, or the like.

### Third Embodiment

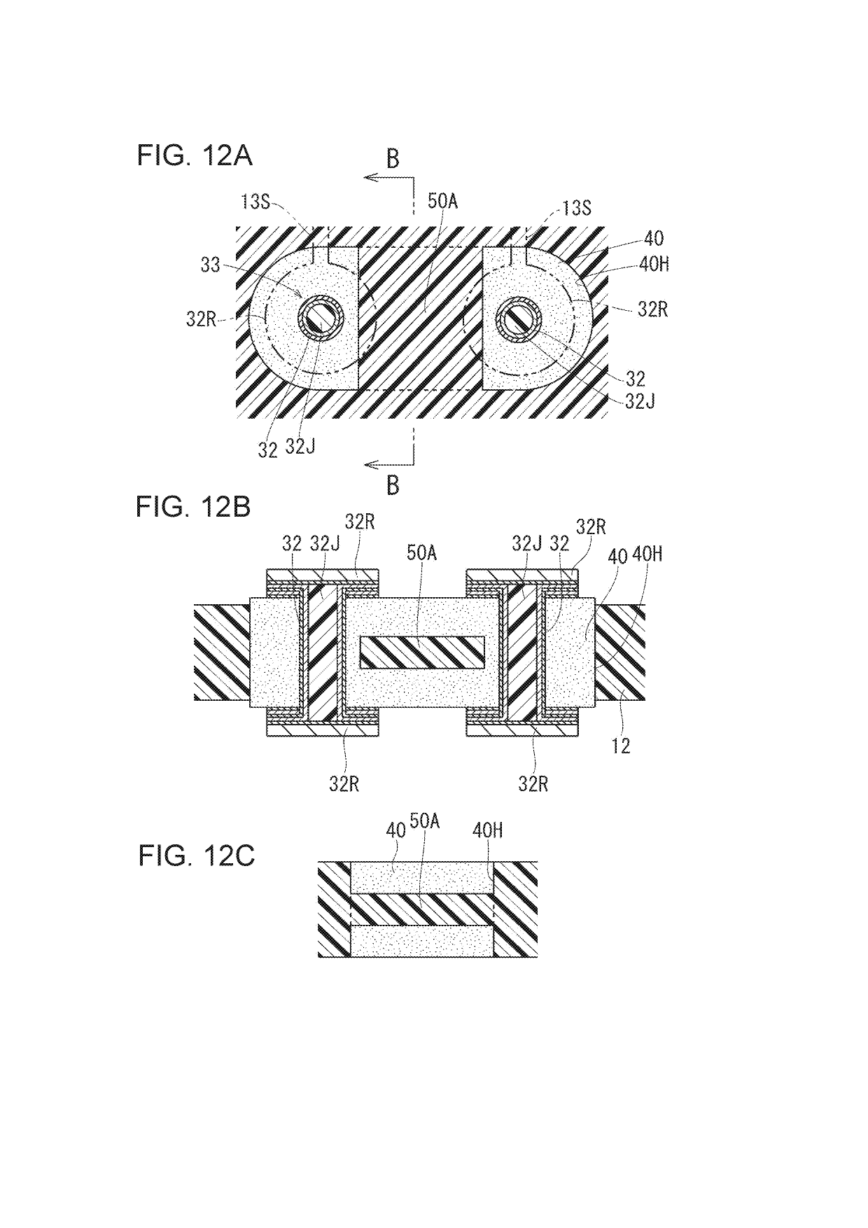

A magnetic resin body 40 according to an embodiment of the present invention is illustrated in FIGS. 12A to 12C, in which an inter-conductor material (50A) is provided so as to bridge between the opposing inner surfaces in the short-side direction of the accommodating portion (40H), is formed at an intermediate position in the thickness direction of the magnetic resin body 40, and is covered on all four sides by the magnetic resin body 40.

### Fourth Embodiment

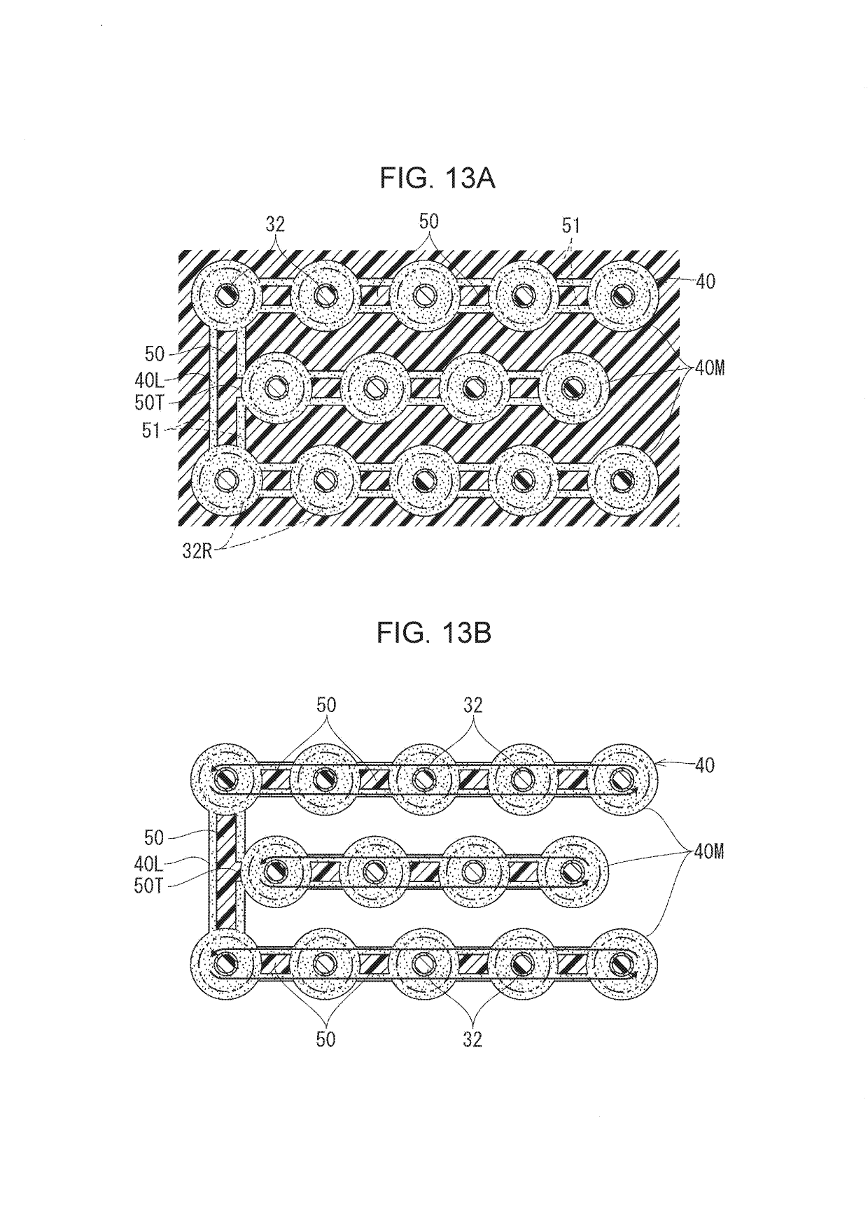

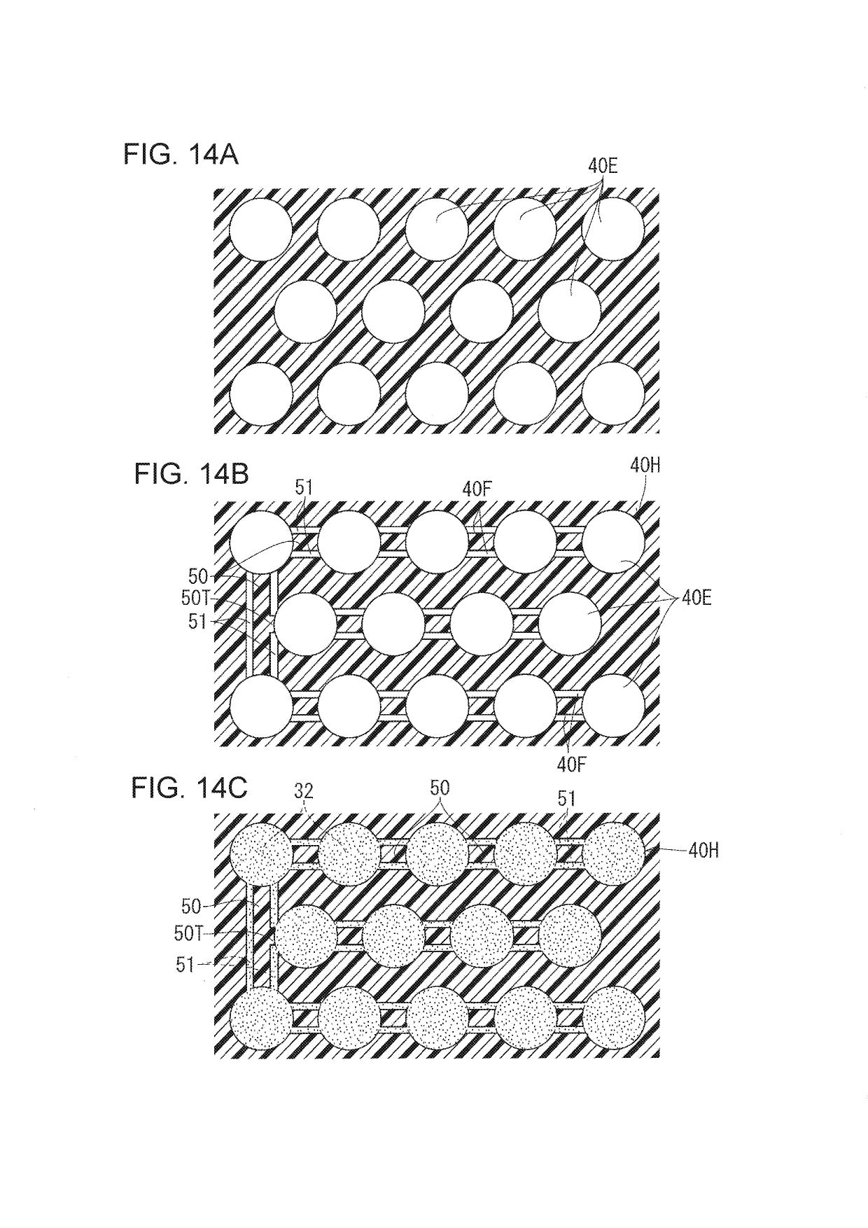

A magnetic resin body 40 according to an embodiment of the present invention is illustrated in FIGS. 13A and 13B, and FIGS. 14A to 14C, and includes, for example, multiple first constituent portions (40M) extending parallel to each other, and a second constituent portion (40L) extending so as to connect one-end portions of the multiple first constituent portions (40M), and has a substantially E-shape in plan view. Each first constituent portion (40M) has, for example, a shape in which circles having a diameter larger than a short side of a rectangle are formed at equal intervals at multiple locations along a longitudinal direction of the rectangle, with through-hole conductors 32 formed in the circular portions, and an inter-conductor material 50 and a pair of connecting portions 51 formed in portions of the rectangle other than the circles. Further, in the multiple first constituent portions (40M), the through-hole conductors 32 are formed at offset positions between adjacent first constituent portions (40M). The second constituent portion (40L) has the same width as the rectangle of the first constituent portions (40M), with an inter-conductor material 50 and a pair of connecting portions 51 formed therein.

In the example illustrated in FIGS. 13A and 13B, the positions of the through-hole conductors 32 are offset between adjacent first constituent portions (40M); however, they need not be offset. Further, in the first constituent portions (40M) and the second constituent portion (40L), the portions where the through-hole conductors 32 are formed are wider than other portions; however, the width may be, for example, substantially constant. Further, in FIGS. 13A and 13B, in the inter-conductor material 50 of the second constituent portion (40L), a protruding portion (50T) is formed extending from an intermediate portion in a longitudinal direction toward an adjacent through-hole conductor 32 side; however, for example, the protruding portion (50T) need not be provided.

In the wiring substrate 10 of the present embodiment, the following processes (1) to (3) are performed in place of the processes (1) to (3) of the first embodiment. (1) First, as illustrated in FIG. 14A, multiple through holes (40E) are formed, for example, by drilling, at positions where the through-hole conductors 32 are to be formed.

(2) Next, as illustrated in FIG. 14B, grooves (40F) are formed, for example by laser processing, on both sides sandwiching the portion that will become the inter-conductor material 50, between the through holes (40E). As a result, an inter-conductor material 50 and a pair of connecting portions 51 are formed between adjacent through holes (40E), and accommodating portions (40H) are obtained.

(3) Next, as illustrated in FIG. 14C, the accommodating portions (40H) are filled with the magnetic resin body 40. It is preferable that the filling of the magnetic resin body 40 is performed using a tape, similar to the process (3) of the first embodiment. Further, the filling of the magnetic resin body 40 is performed using a dispenser instead of vacuum printing. After that, both end surfaces of the magnetic resin body 40 are polished so as to be flush with the metal foil (not illustrated). As a result, the magnetic resin body 40 is obtained.

According to the present embodiment, as illustrated in FIG. 13B, a bypass path of a magnetic path that collectively surrounds multiple through-hole conductors 32 included in each first constituent portions (40M) is formed, and the same effects as the first embodiment are achieved.

### Other Embodiments

In the above first to third embodiments, examples are described in which two through-hole conductors 32 are provided in a common magnetic resin body 40; however, the number of through-hole conductors 32 included in a common magnetic resin body 40 may be three or more.

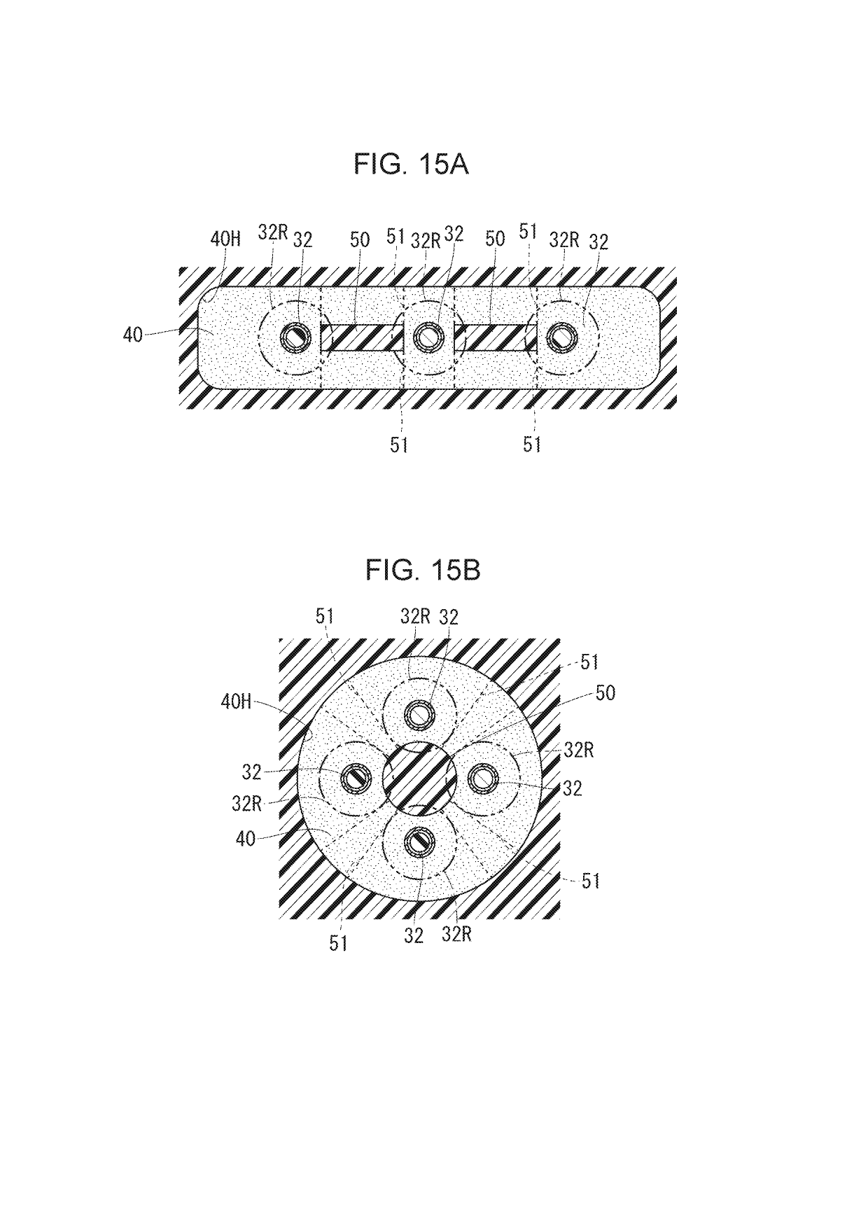

The shape of the magnetic resin body 40 is not limited to an oval shape or an elliptical shape in plan view, and may be, as illustrated in FIGS. 15A and 15B, a quadrilateral shape, a circular shape, or the like in plan view.

The shape of the inter-conductor material 50 is not limited to a quadrilateral shape in plan view, and may be, as illustrated in FIGS. 13A and 13B and FIG. 15B, for example, a polygonal shape, a circular shape, an irregular shape, or the like. Further, the connecting portions 51 connecting to the inter-conductor material 50 are not limited to a pair, and may be only one, or may be three or more (see FIG. 15B).

A wiring substrate may have a magnetic resin body provided in a core substrate and multiple through-hole conductors provided in the magnetic resin body (see, for example, Japanese Patent Application Laid-Open Publication No. 2021-97128). For the above-described wiring substrate, improvement in inductance is desirable.

A wiring substrate according to an embodiment of the present invention includes: a core substrate partially constituted by a magnetic resin body; and multiple through-hole conductors penetrating the common magnetic resin body. An inter-conductor material that has lower magnetism than the magnetic resin body or is non-magnetic is provided between the through-hole conductors in the magnetic resin body.

Another embodiment of the present invention is a method for manufacturing a wiring substrate. The wiring substrate includes: a core substrate partially constituted by a magnetic resin body; and multiple through-hole conductors penetrating the common magnetic resin body. An inter-conductor material that has lower magnetism than the magnetic resin body or is non-magnetic is formed between the through-hole conductors in the magnetic resin body.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate comprising a main body and a magnetic resin body; and
a plurality of through-hole conductors formed in the magnetic resin body in the core substrate such that the plurality of through-hole conductors is penetrating through the magnetic resin body in the core substrate,
wherein the core substrate is formed such that an inter-conductor material is positioned between the through-hole conductors in the magnetic resin body and that the inter-conductor material has magnetism that is lower than magnetism of the magnetic resin body or is non-magnetic.

2. The wiring substrate according to claim 1, further comprising:
a circuit configured to flow current through the plurality of through-hole conductors in a same direction.

3. The wiring substrate according to claim 1, wherein the core substrate is formed such that the main body and the inter-conductor material are formed of a same material.

4. The wiring substrate according to claim 3, wherein the core substrate includes a connecting portion protruding from the main body into the magnetic resin body and connected to the inter-conductor material.

5. The wiring substrate according to claim 4, wherein the core substrate is formed such that the connecting portion is formed at an intermediate position in a thickness direction of the main body.

6. The wiring substrate according to claim 1, wherein the core substrate is formed such that the magnetic body has a through hole and that the inter-conductor material comprises resin material filling the through hole formed in the magnetic resin body.

7. The wiring substrate according to claim 1, wherein the core substrate is formed such that the magnetic body has a recess and that the inter-conductor material comprises resin material filling the recess formed in the magnetic resin body.

8. The wiring substrate according to claim 2, wherein the core substrate is formed such that the main body and the inter-conductor material are formed of a same material.

9. The wiring substrate according to claim 8, wherein the core substrate includes a connecting portion protruding from the main body into the magnetic resin body and connected to the inter-conductor material.

10. The wiring substrate according to claim 9, wherein the core substrate is formed such that the connecting portion is formed at an intermediate position in a thickness direction of the main body.

11. The wiring substrate according to claim 2, wherein the core substrate is formed such that the magnetic body has a through hole and that the inter-conductor material comprises resin material filling the through hole formed in the magnetic resin body.

12. The wiring substrate according to claim 2, wherein the core substrate is formed such that the magnetic body has a recess and that the inter-conductor material comprises resin material filling the recess formed in the magnetic resin body.

13. The wiring substrate according to claim 3, wherein the core substrate is formed such that the magnetic body has a through hole and that the inter-conductor material comprises resin material filling the through hole formed in the magnetic resin body.

14. The wiring substrate according to claim 3, wherein the core substrate is formed such that the magnetic body has a recess and that the inter-conductor material comprises resin material filling the recess formed in the magnetic resin body.

15. The wiring substrate according to claim 4, wherein the core substrate is formed such that the magnetic body has a through hole and that the inter-conductor material comprises resin material filling the through hole formed in the magnetic resin body.

16. The wiring substrate according to claim 4, wherein the core substrate is formed such that the magnetic body has a recess and that the inter-conductor material comprises resin material filling the recess formed in the magnetic resin body.

17. A method for manufacturing a wiring substrate, comprising:
forming an accommodating portion in a main body of a core substrate;
filling the accommodating portion formed in the main body of the core substrate with a magnetic resin body paste such that a magnetic resin body is formed in the core substrate;
forming a plurality of through-hole conductors in the magnetic resin body of the core substrate such that the plurality of through-hole conductors penetrates through the magnetic resin body in the core substrate; and
forming an inter-conductor material in the core substrate such that the inter-conductor material is positioned between the through-hole conductors in the magnetic resin body of the core substrate and that the inter-conductor material has magnetism that is lower than the magnetic resin body or is non-magnetic.

18. The method of claim 17, wherein the forming of the accommodating portion includes forming a connecting portion extending inward from an inner surface of the accommodating portion and connected to the inter-conductor material.

19. The method of claim 18, wherein the forming of the accommodating portion includes forming a plurality of annular grooves surrounding a portion corresponding to the inter-conductor material on front and back surfaces of the main body portion of the core substrate respectively, forming a plurality of through holes overlapping the grooves such that the through holes are spaced apart from each other, and leaving the inter-conductor material between the through holes such that the inter-conductor material has a same height as a total height of the main body and the connecting portion formed at an intermediate position in a thickness direction of the main body portion.

20. The method claim 19, wherein the grooves are formed by laser processing, and the through holes are formed by drilling.
